(19) United States
(12) Patent Application Publication
(10) Pub. No.: US 2009/0242911 A1
(43) Pub. Date: Oct. 1, 2009

(54) ORGANIC LIGHT-EMITTING DISPLAY DEVICE

(76) Inventors: Shingo Ishihara, Mito (JP); Masao Shimizu, Hitachi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/388,600

(22) Filed: Feb. 19, 2009

(30) Foreign Application Priority Data
Mar. 31, 2008 (JP) JP2008-090957

(51) Int. Cl. H01L 51/50

(52) U.S. Cl. 257/89; 257/40; 257/E51.022

(57) ABSTRACT

An object of the present invention is to provide an organic light-emitting display device using a number of organic light-emitting elements that emit lights of different colors, wherein the life of the organic light-emitting elements that emits light of a color having a short life can be prolonged. According to the present invention, a hole injection layer 7, an α-NPD vapor deposited film 8, an n doped electron transportation layer 11 and a p doped hole transportation layer 12, which are patterned to the same size as B sub-pixels, a DNA vapor deposited film 13, an electron injection layer 14 and an upper electrode 15 are formed on a lower electrode 5 in a B sub-pixel. The α-NPD vapor deposited film 8 and the DNA vapor deposited film 13 function as a blue light-emitting layer and exhibit the same properties as when a blue light-emitting element made up of a lower electrode 5, a hole injection layer 7, an α-NPD vapor deposited film 8 and an n doped electron transportation layer 11 and a blue light-emitting element made up of a p doped hole transportation layer 12, a DNA vapor deposited film 13, an electron injection layer 14 and an upper electrode 15 are connected in series. Therefore, it becomes possible to lower the value of a current required for certain brightness, and thus, the life can be prolonged.

The present application claims priority over Japanese Application JP2008-090957 filed on Mar. 31, 2008, the contents of which are hereby incorporated into this application by reference.

### BACKGROUND OF THE INVENTION

(1) Field of the Invention

The present invention relates to an organic light-emitting display device and an organic light-emitting element that forms an organic light-emitting display device.

(2) Related Art Statement

Self-luminous organic electroluminescence elements (hereinafter referred to as “organic light-emitting elements”) are expected to be used for thin display devices and lighting apparatuses for liquid crystal display devices.

Organic light-emitting display devices are formed of a number of organic light-emitting elements that form pixels on a substrate and a drive layer for driving these organic light-emitting elements.

The organic light-emitting elements have a structure where a number of organic layers are sandwiched between a lower electrode and an upper electrode. In addition, the number of organic layers include a transportation layer for transporting holes, a transportation layer for transporting electrons, and a light-emitting layer where holes and electrons recombine. In addition, when a voltage is applied across the two electrodes of the organic light emitting elements, holes and electrons injected through the electrodes recombine in the light-emitting layer, so that light is emitted.

The organic light-emitting display devices are formed of organic light-emitting elements which emit light of a number of colors, so that color display is possible. A general combination of colors for emitted light is red, green and blue. The life of the organic light-emitting display devices is determined by the organic light-emitting elements having the shortest life. Therefore, it is necessary to make the life of organic light-emitting elements which emit light of all colors long.

At present, the life of organic light emitting-elements which emit blue light tends to be shorter than the life of red organic light-emitting elements and green light-emitting elements. Therefore, it is a goal to prolong the life of blue organic light-emitting elements in order to achieve long-term reliability for organic light-emitting display devices.

In order to achieve this goal, multi-photon emission structures have been disclosed in recent years as a structure for prolonging the life of elements (see for example Patent Document 1). In the multi-photon emission structure in Patent Document 1, light-emitting units, including light-emitting layers and transportation layers, are layered between a lower electrode and an upper electrode via charge generating layers. These charge generating layers supply carriers for an equal amount of charge to the upper and lower light-emitting units.

As a result, the total amount of light emission becomes the sum of light emission from the respective light emitting units, and the efficiency of the current increases. Therefore, the amount of current required to gain a certain brightness becomes small, and therefore, the life is prolonged.

[Patent Document 1] Japanese Unexamined Patent Publication 2003-272860

### SUMMARY OF THE INVENTION

### Problem to be Solved by the Invention

In general structures, the transportation layers are formed throughout the entirety of the display panel region, and commonly used as transportation layers for a number of organic light-emitting elements. In such configurations, only the light-emitting layer needs to be patterned so as to have the size of pixels.

High-precision masks are generally used for patterning layers to the size of pixels in this manner. High-precision masks may raise problems, for example they may cause mass-producibility to deteriorate when the mask is changed, and thus, it is desirable to use a smaller number of masks.

In the case where the structure in Patent Document 1 is used for an organic light-emitting display device, it is necessary to form a number of light-emitting units in organic light-emitting elements for emitting light of a number of colors. Thus, when a number of light-emitting units are formed, the number of times the high-precision masks are used for the formation of a light-emitting layer increases, and thus there is a problem, such that the mass-producibility deteriorates.

An object of the present invention is to provide an organic light-emitting display device using a number of organic light-emitting elements which emit light of different colors, where the life of organic light-emitting elements which emit a color of light having a short life is prolonged.

### Means for Solving Problem

The present invention provides a two-stage multi-photon emission structure where a charge generating layer is used instead of a light-emitting layer in organic light-emitting elements having a short-life, so that the transportation layers on the two sides of the charge generating layer function as light-emitting layers.

Concretely, an organic light-emitting display device formed of a number of organic light-emitting elements which emit light of different colors is characterized in that at least a transportation layer for transporting holes and a transportation layer for transporting electrons are formed throughout the entirety of the display region, a patterned charge generating layer is formed for organic light-emitting elements which emit light of one color from the organic light-emitting elements, and a light-emitting layer is formed for organic light-emitting elements which emit light of other colors.

In addition, the present invention provides an organic light-emitting display device made up of a number of organic light-emitting elements which emit light of different colors, characterized in that at least a transportation layer for transporting holes and a transportation layer for transporting electrons are formed throughout the entirety of the display region, a patterned charge generating layer is formed for two types of organic light-emitting elements which emit light of two colors from among the organic light-emitting elements, and a light-emitting layer is formed for organic light-emitting elements which emit light of other colors.

### Effects of the Invention

According to the present invention, the life of organic light-emitting elements which emit light of a color having a short life can be prolonged in an organic light-emitting display device using a number of organic light-emitting elements which emit light of different colors.

### BRIEF DESCRIPTION OF THE DRAWINGS

FIG. 1 is a cross sectional diagram showing pixels in an organic light-emitting display device;

FIG. 2 is a schematic cross sectional diagram showing the B sub-pixel shown in FIG. 1;

FIG. 3 is a cross sectional diagram showing pixels in another organic light-emitting display device;

FIG. 4 is a schematic cross sectional diagram showing the B sub-pixel shown in FIG. 3;

FIG. 5 is a cross sectional diagram showing pixels in another organic light-emitting display device;

FIG. 6 is a schematic cross sectional diagram showing the B sub-pixel shown in FIG. 5;

FIG. 7 is a cross sectional diagram showing pixels in another organic light-emitting display device;

FIG. 8 is a schematic cross sectional diagram showing the G sub-pixel and the B-sub-pixel shown in FIG. 7;

FIG. 9 is a cross sectional diagram showing pixels in another organic light-emitting display device;

FIG. 10 is a schematic cross sectional diagram showing the G sub-pixel and the B-sub-pixel shown in FIG. 9;

FIG. 11 is a cross sectional diagram showing pixels in another organic light-emitting display device; and

FIG. 12 is a schematic cross sectional diagram showing the R sub-pixel, the G sub-pixel and the B-sub-pixel shown in FIG. 11.

### EXPLANATION OF SYMBOLS

1 . . . substrate
2 . . . first interlayer insulating film
3 . . . red lower electrode
4 . . . green lower electrode
5 . . . blue lower electrode
6 . . . second interlayer insulating film
7 . . . hole injection layer
8 . . . hole transportation layer
9 . . . red light emitting layer
10, 47, 50, 57, 60 . . . green light emitting layer
11, 23, 43, 53 . . . n doped electron transportation layer
12, 24, 44, 54 . . . p doped hole transportation layer
13 . . . electron transportation layer
14 . . . electron injection layer
15 . . . upper electrode
16 . . . OLED substrate
17 . . . sealing substrate
18, 27, 37 . . . first blue OLED
19, 28, 38 . . . second blue OLED
21, 26, 41, 46 . . . blue light-emitting layer
22, 32, 42, 48, 58, 62 . . . electron transportation layer
25, 35, 45, 49, 59, 61 . . . hole transportation layer

### DETAILED DESCRIPTION OF THE INVENTION

### Best Mode for Carrying Out the Invention

As described above, the present invention was achieved as a result of examination of the structure of display devices using light-emitting elements having a short life and light-emitting elements having a long life, in order to provide a display device having a long life and make the manufacture of display devices easy, and it is possible to use the invention widely to solve problems with the life of a display device being short because light-emitting elements have a different life.

As a means for this, a hole transportation layer and an electron transportation layer are provided throughout the entirety of the display device, as described above, and a light-emitting layer is formed for elements having a long life, and a charge generating layer is formed for elements having a short life, between the transportation layers. In addition, at least the hole transportation layer or the electron transportation layer is used as a layer for emitting light of a color emitted by elements having a short life.

Accordingly, the invention provides an organic light-emitting display device having at least two organic light-emitting elements, characterized in that each organic light-emitting element has a pair of electrodes for applying a voltage, and a continuous hole transportation layer for transporting holes and electron transporting layer for transporting electrons, formed throughout the entirety of the display region provided between the above described electrodes, the above described first organic light-emitting element has a light emitting layer for emitting light of the color of the above described first organic light-emitting element provided separately from the above described second element between the above described hole transportation layer and the above described electron transportation layer, the above describe second organic light-emitting element has a charge generating layer provided separately from the above described first element between the above described hole transportation layer and the above described electron transportation layer, and at least the above the described hole transportation layer or the above described hole transportation layer is a layer for emitting light of the color of the above described second organic light-emitting element.

At present, light-emitting elements which emit blue light have a shorter life than red and green light-emitting elements. Organic light-emitting elements having a hole transportation layer and an electron transportation layer as light-emitting layers, and a charge generating layer provided between these are provided for blue pixels. In addition, an element structure where light-emitting layers for different colors are provided between the hole transportation layer and the charge generating layer is provided for pixels for other colors.

In this configuration, blue pixels have a structure where blue OLED's are connected in series, so that the brightness of light emitted by respective organic light-emitting elements can be made half of the desired brightness for the organic light-emitting display device, and therefore, the efficiency of blue light-emitting elements can be increased, and the life can be prolonged, so that the life of the organic light-emitting display device can be prolonged.

In the following, an example of an organic light-emitting display device according to the present invention is described. Here, the present invention is not limited to the following example.

In the present specification, organic light-emitting elements have the following structure. That is to say, organic light-emitting elements are formed of substrate/lower electrode/first injection layer/first transportation layer/light emitting layer/second transportation layer/second injection layer/upper electrode/protective layer or sealing substrate (facing substrate) in this order.

There are to combinations for the lower electrode and the upper electrode.

The first is a configuration where the lower electrode is an anode and the upper electrode is a cathode. In this case, the first injection layer and the first transportation layer respectively become a hole injection layer and a hole transportation layer, and the second transportation layer and the second injection layer respectively become an electron transportation layer and an electron injection layer.

The other is a configuration where the lower electrode is a cathode and the upper electrode is an anode. In this case, the first injection layer and the first transportation layer respectively become an electron injection layer and an electron transportation layer, and the second transportation layer and the second injection layer respectively become a hole transportation layer and a hole injection layer.

In addition, it is possible for the above described configuration not to have a first injection layer or a second injection layer. Furthermore, a structure where the first transportation layer or the second transportation layer works as a light emitting layer is also possible.

A combination of an upper electrode and a lower electrode where one electrode transmits emitted light and the other electrode reflects emitted light is desirable. In this case, light is emitted through the electrode which transmits light, and therefore, the electrode is referred to as light emitting electrode.

Meanwhile, the electrode which reflects light is referred to as reflective electrode. The structure where the upper electrode is a light emitting electrode is referred to as top emission structure. Meanwhile, the structure where the lower electrode is a light emitting electrode is referred to as bottom emission structure.

Any substrate can be selected, as long as it is made of an insulating material.

Concretely, inorganic materials, such as glass and sintered alumina bodies, as well as various types of insulating plastics, such as polyimide films, polyester films, polyethylene films, polyphenylene sulfide films and polyparaxylene, can be used.

In addition, a metal material (for example stainless steel, copper or an alloy including any of these metals) can be used without any problem, as long as an insulating material as that described above is formed on the surface.

It is desirable for the anode to be made of a conductive film having a large work function, in order to increase the efficiency of hole injection.

Concretely, gold, platinum and the like can be cited, but the invention is not limited to using these materials. In addition, materials of two metal elements, such as indium tin oxide (ITO) and indium zinc oxide (IZO), indium germanium oxide, and materials of three metal elements, such as indium tin zinc oxide, may be used for the anode. In addition, a composition having tin oxide, zinc oxide or the like as a main component, in addition to indium oxide, may be used. In addition, ITO having a composition including 5 weight % to 10 weight % of tin oxide relative to indium oxide is often used.

A sputtering method, an EB vapor deposition method, an iron plating method and the like can be cited for the manufacturing method for semiconductor oxide. The work function of the ITO film and the IZO film is 4.6 eV and 4.6 eV, respectively. It is possible to increase it to 5.2 eV through irradiation with UV ozone or through oxygen plasma processing.

ITO films become of a polycrystal state when fabricated in accordance with a sputtering method under such conditions that the temperature of the substrate is as high as approximately 200° C. In the polycrystal state, the flatness on the surface is poor, due to crystal grains, and therefore, it is desirable to polish the surface.

In addition, it is desirable to use another method, according to which the film is formed in an amorphous state and converted to a polycrystal state through heating.

In addition, it is not necessary to use a material having a large work function for the anode when the above described hole injection layer is provided, and a conventional conductive film may be used. Concretely, metals, such as aluminum, indium, molybdenum and nickel, alloys using these metals, and inorganic materials, such as polysilicon, amorphous silicon, tin oxide, indium oxide and indium tin oxide (ITO) are desirable.

In addition, in the case where the anode is used as a reflective electrode, a multilayer film where a transparent conductive film is layered on a reflective electrode which is a metal film is also possible. The respective layers are desirably the above described materials. In addition, organic materials, such as polyaniline and polythiophene, and conductive inks may be used in accordance with an application method that can provide a simple process for formation. The anode is not limited to being made of these materials, and two or more of the materials may be used together.

The hole injection layer has a function of lowering the injection barrier for the anode and the hole transportation layer. Accordingly, materials having an appropriate ionization potential are desirable for the hole injection layer. In addition, it is desirable for the hole injection layer to have a function of evening the uneven surface of the base layer.

Concretely, copper phthalocyanine, starburst amine compounds, polyaniline, polythiophene, vanadium oxide, molybdenum oxide, ruthenium oxide, aluminum oxide and the like can be cited, but the invention is not limited to using these.

In addition, the hole transportation layer has a function of transporting holes and injecting them in the light emitting layer. Therefore, it is desirable for the hole transportation layer to be made of a hole transporting material having high hole mobility. In addition, it is desirable for the hole transportation layer to have such properties as to be chemically stable and to have a small ionization potential, a small electron affinity and a high glass transition temperature.

Concretely, N,N′-bis(3-methylphenyl)-N,N′-diphenyl-[1,1′-biphenyl]-4,4′diamine (TPD), 4,4′-bis[N-(1-naphthyl)-N-phenylamino]biphenyl (α-NPD), 4,4′,4″-tri(N-carbazolyl) triphenylamine (TCTA), 1,3,5-tris[N-(4-diphenylaminophenyl) phenylamino]benzene (p-DPA-TDAB), 4,4′,4″-tris(N-carbazole) triphenylamine (TCTA), 1,3,5-tris[N,N-bis(2-methylphenyl)-amino]-benzene (o-MTDAB), 1,3,5-tris[N,N-bis(3-methylphenyl)-amino]-benzene (m-MTDAB), 1,3,5-tris[N,N-bis(4-methylphenyl)-amino]-benzene (p-MTDAB), 4,4′,4″-tris[1-naphthyl(phenyl) amino]triphenylamine (1-TNATA), 4,4′,4″-tris[2-naphthyl(phenyl)amino]triphenylamine (2-TNATA), 4,4′,4″-tris[biphenyl-4-yl-(3-methylphenyl)amino]triphenylamine (p-PMTDATA), 4,4′,4″-tris[9,9-dimethylfluorene-2-yl(phenyl)amino]triphenylamine (TFATA), 4,4′,4″-tris(N-carbazoyl)triphenylamine (TCTA), 1,3,5-tris-[N-(4-diphenylaminophenyl)phenylamino]benzene (p-DPA-TDAB), 1,3,5-tris{4-[methylphenyl(phenyl)amino]phenyl}benzene (MTDAPB), N,N′-di(biphenyl-4-yl)-N,N′-diphenyl[1,1′-biphenyl]-4,4′-diamine (p-BPD), N,N′-bis(9,9-dimethylfluorene-2-yl)-N,N′-diphenyl fluorene-2,7-diamine (PFFA), N,N, N′,N′-tetrakis(9,9-dimethylfluorene-2-yl)-[1,1-biphenyl]-4,4′-diamine (FFD), (NDA) PP, and 4,4′-bis[N,N′-(3-tryl)amino]-3-3′-dimethylbiphenyl (HMTPD) can be cited as examples. Of course the invention is not limited to using these materials, and two or more of the materials may be used together.

In addition, a hole transporting material as that described above can be used with an oxidizing agent added as the hole transporting layer, in order to lower the barrier for the anode or increase the electrical conductivity

Lewis acid compounds, such as ferric chloride, ammonium chloride, gallium chloride, indium chloride and antimony pentachloride, and electron acceptor compounds, such as trinitrofluorene, can be cited as concrete examples of the oxidizing agent. The invention is, or course, not limited to using these materials, and two or more of the materials may be used together.

The light emitting layers are layers where injected holes and electrons recombine so that light having a wavelength unique to the material is emitted. There are light emitting layers where the host material forming the light emitting layer emits light and a microscopic amount of a dopant material added to the host emits light.

As concrete examples of the host material, distyryl arylene derivatives (DPVBi), silole derivatives having a benzene ring as a skeleton (2PSP), oxodiazol derivatives having triphenylamine structures at the two ends (EM2), perinone derivatives having a phenanthrene group (P1), oligothiophene derivatives having a triphenylamine structure at the two ends (BMA-3T), perylene derivatives (tBu-PTC), tris(8-quinolynol) aluminum, polyparaphenylene vinylene derivatives, polythiophene derivatives, polyparaphenylene derivatives, polysilane derivatives and polyacetylene derivatives can be cited.

In addition, as concrete examples of the dopant material used in the light emitting layer, quinacridone, coumarin 6, Nile red, rubrene, 4-(dicyanomethylene)-2-methyl-6-(para-dimethylaminostearyl)-4H-pyran (DCM), dicarbazol derivatives, porphyrin platinum complexes (PtOEP), and iridium complexes (Ir(ppy)3) can be cited. The light emitting layer is not limited to these materials, and two or more of the materials may be used together.

Electron transportation layers transport electrons and have a function of injecting them in the light emitting layer. Therefore, it is desirable for the electron transportation layer to be formed of an electron transporting material having high electron mobility.

Concretely, tris(8-quinolinol) aluminum, oxadiazol derivatives, silole derivatives, zinc, benzothiazol complexes, and basocuproin (BCP) are desirable.

It is desirable for the electron transportation layer to contain a reducing agent in the above described electron transporting material, so that the barrier with the cathode is low and the electron conductivity is high.

As concrete examples of the reducing agent, alkali metals, alkali earth metals, alkali metal oxides, alkali earth oxides, rare earth oxides, alkali metal halides, alkali earth halides, rare earth halides and complexes of an alkali metal and an aromatic compound can be cited. Particularly preferable alkali metals are Cs, Li, Na and K.

Here, the electron injection layer is used to increase the efficiency of electron injection from the cathode to the electron transportation layer.

Concretely, as the material of the electron injection layer, lithium fluoride, magnesium fluoride, calcium fluoride, strontium fluoride, barium fluoride, magnesium oxide and aluminum oxide are desirable.

It is desirable to use a conductive film having a small work function for the cathode in order to increase the efficiency of electron injection.

As concrete examples of the material for the cathode, magnesium-silver alloys, aluminum-lithium alloys, aluminum-calcium alloys, aluminum-magnesium alloys and metal calcium can be cited.

Meanwhile, it is not necessary to use a material having a low work function, in terms of the conditions for the cathode in the case where the above described electron injecting layer is provided on the cathode, and thus, it is possible to use a general metal material.

As concrete examples of the material for the cathode in this case, metals, such as aluminum, indium, molybdenum and nickel, alloys using these metals, polysilicon and amorphous silicon can be used.

The protective layer is formed on the upper electrode and has a function of preventing H₂O and O₂ in the air from entering the upper electrode or the organic layer beneath the upper electrode.

Concretely, as the material for the protective layer, inorganic materials, such as SiO₂, SiNx and Al₂O₃, and organic materials, such as polychloroprene, polyethylene terephthalate, polyoxymethylene, polyvinyl chloride, polyvinylidene fluoride, cyanoethyl pullulan, polymethyl methacrylate, polysulfon, polycarbonate and polyimide can be used.

When the organic light-emitting elements described above are used for the respective pixels, an organic light-emitting display device can be provided. Here, the organic light-emitting display device is a display device using organic light-emitting elements for the pixels. This organic light-emitting display device includes a simple matrix organic light-emitting display device and an active matrix organic light-emitting display device.

In simple matrix organic light-emitting display devices, organic layers, for example a hole transportation layer, a light-emitting layer and an electron transportation layer, are formed in such locations that a number of anode lines and cathode lines cross, so that each pixel is turned on only during a selected period of time during one frame period. The selected period of time has a time width gained by dividing one frame period by the number of anode lines.

In active matrix organic light-emitting display devices, a drive element formed of a switching element including two to four thin film transistors and a capacitor is connected to the organic EL (light emitting) element for each pixel, so that it is possible to turn on all of the pixels during one frame. Therefore, it is not necessary to increase the brightness, and it is possible to prolong the life of the organic light-emitting elements. It is desirable to use a color converting layer in the organic light-emitting display device.

A great number of pixels are aligned longitudinally and laterally on the screen of the display device, and these are minimum units for displaying letters and graphics in the display region.

In addition, sub-pixels are minimum units which further divide the pixels on the color display devices. The structure for color images is generally formed of sub-pixels for three colors: green, red and blue.

In addition, the display region is a region displaying an image on the display device.

Current supply lines are wires connecting the power supply to organic EL elements. In the active matrix organic light-emitting display devices, first current supply lines are wires for connecting the power supply to the lower electrodes of the organic EL elements via the source and drain electrodes of the switching elements. In addition, in the active matrix organic light-emitting display apparatuses, second current supply lines are wires for connecting the power supply to the upper electrodes, which are a common electrode for the pixels.

### First Embodiment

The organic light-emitting display apparatuses according to embodiments of the present invention are described in reference to the drawings.

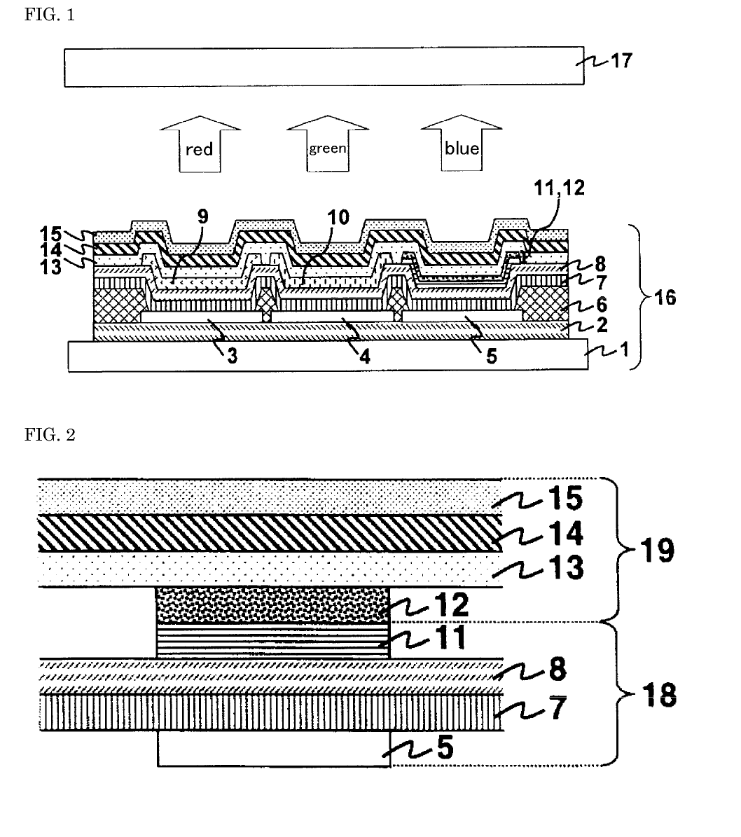

FIG. 1 is a cross sectional diagram showing a pixel in an organic light-emitting display device. In addition, FIG. 2 is a schematic cross sectional diagram showing a blue light-emitting element.

Though not shown in FIG. 1, a number of scan lines are aligned with constant intervals between the glass substrate 1 and the first layer insulating film 2, and at the same time, signal lines for transmitting image information are aligned with constant intervals in such a direction as to cross the scan lines.

That is to say, scan lines and signal lines are aligned in a grid, and the regions surrounded by scan lines and signal lines are display regions for pixels or sub-pixels.

Furthermore, a number of first current supply lines connected to the power supply are aligned on the glass substrate 1 so as to be parallel to the signal lines. In addition, a number of second current supply lines connected to the power supply are aligned parallel to the scan lines. The scan lines, the signal lines, the first current supply lines and the second current supply lines are formed on the glass substrate 1 as wires belonging to wire layers with interlayer insulating films in between.

A drive layer for driving the organic layer in the pixels is formed on the glass substrate 1. This drive layer is formed so as to have first transistors, second transistors and capacitors as drive elements.

The gate electrodes of the first transistors are connected to the scan lines, the source electrodes are connected to the signal lines, and the drain electrodes are connected to the gate electrodes of the second transistors and the lower electrodes of the capacitors. The drain electrodes of the second transistors are connected to the upper electrodes of the capacitors and the first current supply lines, and the source electrodes are connected to the lower electrodes 3 to 5.

In addition, an acryl insulating film having a film thickness of 2 μm is formed on the substrate as a first interlayer insulating film 2. Here, in the present embodiment, an acryl insulating film is used for the first interlayer insulating film 2, but the invention is not limited to using this, and other organic insulating materials, such as polychloroprene, polyethylene terephthalate, polyoxymethylene, polyvinyl chloride, polyvinylidene fluoride, cyanoethyl pullulan, polymethyl methacrylate, polysulfone, polycarbonate and polyimide can also be used.

In addition, it is possible to use inorganic materials, such as SiO₂, SiNx and Al₂O₃. In addition, an appropriate structure where these are combined in such a manner that an inorganic insulating film is layered on top of an organic insulating film is also possible.

A number of organic light-emitting elements that form pixels, which are minimum units, for color images, are aligned on the upper side of the wire layer.

As shown in FIG. 1, each organic light-emitting element which is a sub-pixel is formed of organic layers, including a hole injection layer 7, a hole transportation layer 8, light-emitting layers 9 and 10, an n doped electron transportation layer 11, a p doped hole transportation layer 12, an electron transportation layer 13 and an electron injection layer 14, as well as lower electrodes 3, 4 and 5 and an upper electrode 15 which sandwich the organic layers.

The lower electrodes 3 to 5 of the organic light-emitting element belonging to the pixel are connected to first current supply lines via transistors, which are drive elements, and the upper electrode 15 of the organic light-emitting elements belonging to each pixel is connected to the second current supply line connected to the power supply.

First, lower electrodes 3 to 5 are formed of ITO on the first interlayer insulating film 2 in accordance with a sputtering method. The film thickness is 150 nm. Next, a second interlayer insulating film 6 is formed, in order to cover the edges of the lower electrodes. Here, though an acryl insulating film is used for the second interlayer insulating film 6, other materials can be used in the same manner as the first interlayer insulating film 2.

Next, 4,4′-bis[N-(1-naphthyl)-N-phenylamino]biphenyl (hereinafter referred to as α-NPD) and vanadium pentaoxide (V₂O₅) are deposited together on the lower electrodes 3 to 5 in accordance with a vacuum vapor deposition method, so that a film having a film thickness of 50 nm is formed. The rate of vapor deposition for the respective materials is determined so that the molecular ratio with which α-NPD and V₂O₅ are mixed is 1:1. This vapor-deposited film is formed over the entire surface of the light-emitting display area and functions as a hole injection layer 7.

Next, an α-NPD film 8 having a film thickness of 20 nm is formed on the hole injection layer 7 in accordance with a vapor deposition method. The rate at which α-NPD is vapor deposited is 0.5 nm/sec. This α-NPD film is formed over the entire of the light-emitting display area and functions as a hole transportation layer in red and green sub-pixels and as a blue light-emitting layer in blue sub-pixels.

Next, the formation of a light-emitting layer in red light-emitting sub-pixels (hereinafter referred to as “R sub-pixels”) on the lower electrode 3 is described.

4,4′-N,N′-dicarbazol-biphenyl (hereinafter referred to as “CBP”) and bis[2-(2′-benzo[4,5-a]thienyl)pyridinate-N,C3′]iridium (acetylacetonate) (hereinafter referred to as “Brp₂Ir(acac)”) are deposited together on the α-NPD film 8 in accordance with a vapor deposition method, so that a film having a film thickness of 40 nm is formed.

The rate at which CBP and Brp₂Ir(acac) are deposited is 0.20 nm/sec and 0.02 nm/sec, respectively. The above described vapor-deposited film functions as an R light-emitting layer 9. In addition, in the R light-emitting layer 9, Brp₂Ir(acac) functions as a dopant which determines the color of emitted light. The vapor-deposited film of CBP and Brp₂Ir(acac) is patterned using a high-precision mask having an opening pattern of the same size as the sub-pixels.

Next, the formation of a light-emitting layer in green light-emitting sub-pixels (hereinafter referred to as “G sub-pixels”) on the lower electrode 4 is described.

CBP and an iridium complex compound (hereinafter referred to as “Ir(ppy)₃”) are vapor deposited together on the α-NPD film 8 in accordance with a vapor deposition method, so that a film having a film thickness of 40 nm is formed. The rate at which CBP and Ir(ppy)₃ is vapor deposited is 0.20 nm/sec and 0.02 nm/sec, respectively. The above described vapor-deposited film functions as a G light-emitting layer 10.

In addition, Ir(ppy)₃ in the G light-emitting layer functions as a dopant for determining the color of emitted light. In addition, the vapor-deposited film of CBP and Ir(ppy)₃ is patterned using a high-precision mask having an opening pattern of the same size as the sub-pixels.

Next, the formation of a charge generating layer in blue light-emitting sub-pixels (hereinafter referred to as “B sub-pixels”) on the lower electrode 5 is described. The charge generating layer is a layer for generating holes and electrons having the same charge through application of a voltage, and supplying these to the upper and lower light-emitting layers. These carriers are combined with holes and electrons supplied to the light-emitting layers from the charge transportation layer side in the light-emitting layers. In the present embodiment, an n doped electron transportation layer and a p doped hole transportation layer are combined in a charge generating layer. Here, any charge generating layer can be used in the present invention, even in the case where it is not a charge generating layer made up of a number of layers, as in the present example.

Tris(8-quinolynol) aluminum (hereinafter referred to as “Alq3”) and cesium (Cs) are deposited together on the α-NPD film 8 in accordance with a vapor deposition method, so that a film having a film thickness of 15 nm is formed. The rate at which Alq3 and Cs are deposited is determined so that the ratio of the molecular concentration is 1:1 in the mixture. The above described vapor-deposited film functions as an n doped electron transportation layer 11.

Next, α-NPD and V₂O₅ are deposited together in accordance with a vapor deposition method, so that a film having a film thickness of 15 nm is formed. The rate at which α-NPD and V₂O₅ are deposited is determined so that the ratio of the molecular concentration is 1:1 in the mixture. The above described vapor-deposited film functions as a p doped hole transportation layer 11. The n doped electron transportation layer 11 and the p doped hole transportation layer 12 are patterned using a high-precision mask having an opening pattern of the same size as the sub-pixels.

In the present embodiment, an organic material having excellent electron transportation is doped with Cs, so that an n doped electron transportation layer is provided. The doped material functions as a reducing agent in the above described electron transporting material, so that the electrical conductivity increases. Concrete examples of the reducing agent are alkali metals, alkali earth metals, alkali metal oxides, alkali earth oxides, rare earth oxides, alkali metal halides, alkali earth halides, rare earth halides and complexes of an alkali metal and an aromatic compound. Particularly preferable alkali metals are Cs, Li, Na and K.

In addition, in the present embodiment, an organic material having excellent hole transportation is doped with V₂O₅ so as to provide a p doped electron transportation layer. The doped material functions as an oxidizing agent in the above described hole transporting material, so that the electrical conductivity increases. Concrete examples of the oxidizing agent are Lewis acid compounds, such as ferric chloride, ammonium chloride, gallium chloride, indium chloride and antimony pentachloride, and electron acceptor compounds, such as trinitrofluorene, vanadium oxide, molybdenum oxide, ruthenium oxide and aluminum oxide. Of course, the invention is not limited to using these materials, and two or more of the materials may be used together.

In addition, though in the present embodiment, an n doped electron transportation layer and a p doped hole transportation layer are layered on top of each other so as to provide a charge generating layer, vanadium oxide, molybdenum oxide, ruthenium oxide, aluminum oxide and the like may be inserted between the two layers.

Next, 9,10-di-(2-naphthyl)anthracene (hereinafter referred to as “ADN”) is vapor deposited on a charge generating layer made up of a red light-emitting layer 9, a green light-emitting layer and an n doped electron transportation layer 11/p doped hole transportation layer 12 in accordance with a vapor deposition method, so that a film 13 having a film thickness of 30 nm is formed. The rate at which ADN is vapor deposited is 0.15 nm/sec. This ADN film is formed over the entire surface of the light-emitting display area, and functions as an electron transportation layer in R sub-pixels and G sub-pixels, and as a light-emitting layer in B sub-pixels.

Next, Alq3 and Cs are vapor deposited together on the ADN vapor deposited film 13 in accordance with a vacuum vapor deposition method so that a film having a film thickness of 30 nm is formed. The rate of vapor deposition is set so that the molecular ratio of this vapor deposited film in the mixture is 1:1. This vapor deposited film is formed on the entire surface of the light emitting display area and functions as the electron injection layer 14.

Next, an Al film having a film thickness of 150 nm is formed in accordance with a vapor deposition method. The rate of vapor deposition of the Al film is 5 nm/sec. This Al film is formed on the entire surface of the light emitting display area and functions as the cathode 15.

Thus, an OLED substrate 16 where a drive layer and a number of organic light-emitting elements are formed on a glass substrate 1 can be fabricated. The OLED substrate 16 is moved to a sealed chamber where a dry nitrogen gas is circulated and a high dew point is maintained without being exposed to air. A glass substrate is introduced into the sealed chamber. This glass substrate becomes a facing substrate 17. A line of light curing resin is applied to an edge portion of a sealing substrate, which is a glass substrate, using a seal dispenser apparatus (not shown). The sealing substrate 17 and the OLED substrate 16 are pasted and pressed together within the sealed chamber. A light shielding plate is placed outside the sealing substrate 17 so that the entirety of the light-emitting element is not exposed to UV rays, and the sealing substrate 17 side is irradiated with UV rays so that the light curing resin is cured. According to the above described manufacturing method, a color organic light-emitting display device having the above described configuration can be provided.

In the above described organic light-emitting display device, R sub-pixels and G sub-pixels have the structure of conventional organic light-emitting elements having anodes 3 and 4, a hole injection layer 7, an α-NPD film 8 which functions as a hole transportation layer, light-emitting layers 9 and 10, an ADN film 13 which functions as an electron transportation layer, an electron injection layer 14 and an upper electrode 15.

Meanwhile, B sub-pixels have a structure of an organic light-emitting element that is different from the conventional structure shown in FIG. 2. The B sub-pixels have a structure where a first blue OLED 18 and a second blue OLED 19 are connected in series.

The first blue OLED 18 is formed of an anode 5, a hole injection layer 7, an α-NPD film 8 and an n doped electron transportation layer 11. The α-NPD film 8 functions as a blue light-emitting layer. That is to say, in the α-NPD film 8, holes are injected from the hole injection layer 7, electrons are injected from the n doped electron transportation layer 11, and after that the two carriers recombine within the α-NPD film 8 so that blue light is emitted.

The second blue OLED 19 is formed of a p doped hole transportation layer 12, an ADN vapor deposited film 13, an electron injection layer 14 and a cathode 15. In the layer configuration, the electron transportation layer 13 functions as a blue light-emitting layer. That is to say, holes are injected into the ADN vapor deposited film 13 from the p doped hole transportation layer 12 and electrons are injected from the electron injection layer 14. After that, the two carriers recombine within the ADN vapor deposited film 13 so that blue light is emitted.

In the B sub-pixels, when a voltage is applied across the anode 5 and the cathode 15, the α-NPD film 8 and the ADN vapor deposited film 13 emit blue light, and therefore, the efficiency in light emission is high. Thus, it becomes possible to lower the current density for a desired brightness, and the life of the blue pixels increases. In addition, in this configuration the layers which are required to be patterned to the same size as pixels are the red and green light-emitting layers, the n doped electron transportation layer and the p doped hole transportation layer, and thus, the hole transportation layer and the electron transportation layer in the red and green sub-pixels can be used in the entire region, including blue sub-pixels, and therefore, the number of high-precision masks used can be reduced.

### Second Embodiment

An example of an organic light-emitting display device according to the second embodiment where the life of blue light-emitting elements can be prolonged, and the efficiency can be increased, by adding a blue light-emitting dopant to the electron transportation layer is described below.

The method for forming a first interlayer insulating film 2, lower electrodes 3 to 5, a second interlayer insulating film 6, a hole injection layer 7 and a hole transportation layer 8 on a glass substrate 1 is the same as in the first embodiment. In addition, the methods for forming a red light-emitting layer 9 in R sub-pixels, a green light-emitting layer 10 in G sub-pixels, an n doped electron transportation layer 11 and a p doped hole transportation layer 12 in B sub-pixels are also the same as in the first embodiment.

ADN and 2,5,8,11-tetra-t-butylperylene (hereinafter referred to as “TBP”) are vapor deposited together on top of a charge generating layer made up of a red light-emitting layer 9, a green light-emitting layer 10 and an n doped electron transportation layer 11/p doped hole transportation layer 12 in accordance with a vapor deposition method so that a film 13 having a film thickness of 30 nm is formed. The rate of vapor deposition of ADN and TBP is 0.20 nm/sec and 0.01 nm/sec respectively. This vapor deposited film is formed on the entire surface of the light-emitting display area and functions as an electron transportation layer in R sub-pixels and G sub-pixels and a blue light-emitting layer in B sub-pixels.

The methods for forming an electron injection layer 14 and a cathode 15 on the vapor deposited film 13 of ADN and TPB are the same as in the first embodiment. In addition, the method for sealing the OLED substrate 16 using a facing substrate 17 is the same as in the first embodiment.

As shown in FIG. 2, the B sub-pixels exhibit the same properties as when the first blue OLED 18 and the second blue OLED 19 are connected in series. The first blue OLED 18 has the same structure as in the first embodiment, and thus has equal properties.

Meanwhile, in the second blue OLED 19, the vapor deposited film 13 of ADN and TPB functions as a light-emitting layer. TPB is added to the light-emitting layer as a blue dopant, and therefore, the efficiency is high.

Meanwhile, R sub-pixels and G sub-pixels are organic light-emitting elements formed of anodes 3 and 4, a hole injection layer 7, an α-NPD film 8 which functions as a hole transportation layer, light-emitting layers 9 and 10, a vapor deposition film 13 of ADN and TPB that functions as an electron transportation layer, an electron injection layer 14 and an upper electrode 15. TPB, which functions as a blue dopant, is added to the vapor deposited film 13 of ADN and TPB, which functions as an electron transportation layer. Therefore, the light-emitting layers 9 and 10 emit red light and green light, and in addition, it is possible for the electron transportation layer to emit blue light.

In the combination of materials that form the red light-emitting layer 9 and the green light-emitting layer 10, however, the lights are mainly emitted from the interface between the hole transportation layer and the light-emitting layer. That is to say, electrons propagate through the red light-emitting layer 9 and the green light-emitting layer 10 so as to recombine with holes in the above described interface. Therefore, the number of holes that propagate through the light-emitting layers 9 and 10 is small, and thus, blue light is prohibited from being emitted from the electron transportation layer with the red and green light emissions not being greatly affected.

### Third Embodiment

An example of an organic light-emitting display device according to the third embodiment where the life of blue light-emitting elements can be prolonged, and the efficiency can be increased, by adding a blue light-emitting dopant to the hole transportation layer and the electron transportation layer is described below. The methods for forming a first interlayer insulting film 2, lower electrodes 3 to 5, a second interlayer insulating film 6 and a hole injection layer 7 on a glass substrate 1 are the same as in the first embodiment.

Next, a vapor deposited film 8 is formed on the hole injection layer 7 of α-NPD and TPB. TPB, which functions as a blue dopant, is added to the vapor deposited film 8 made of α-NPD and TPB, and thus, the efficiency in light emission is high.

A red light-emitting layer 9 is formed in the R sub-pixel region, a green light-emitting layer 10 is formed in the G sub-pixel region, and an n doped electron transportation layer 11 and a p doped hole transportation layer 12 are formed in the B sub-pixel region on the vapor deposited film 8 made of α-NPD and TPB in the same manner as in the first embodiment.

ADN and TBP are vapor deposited together on top of the charge generating layer made up of a red light-emitting layer 9, a green light-emitting layer 10 and an n doped electron transportation layer 11/p doped hole transportation layer 12 in accordance with a vacuum vapor deposition method so that a film 13 having a film thickness of 30 nm is provided. The method for forming the film 13 is the same as in the second embodiment.

The methods for forming an electron injection layer 14 and a cathode 15 on top of vapor deposited film 13 of ADN and TPB are the same as in the first embodiment. In addition, the method for sealing the OLED substrate 16 using a facing substrate 17 is the same as in the first embodiment.

As shown in FIG. 2, the B sub-pixels have a structure where a first blue OLED 18 and a second blue OLED 19 are connected in series.

In the first blue OLED 18, the vapor deposited film 8 made of α-NPD and TPB functions as a light-emitting layer. TPB, which functions as a blue dopant, is added to the light-emitting layer, and therefore, the efficiency is high.

In addition, in the second blue OLED 19, the vapor deposited film 13 of ADN and TPB functions as a light-emitting layer. TPB, which functions as a blue dopant, is added to the light-emitting layer, and therefore, the efficiency is high.

Meanwhile, R sub-pixels and G sub-pixels are organic light-emitting elements formed of anodes 3 and 4, a hole injection layer 7, a vapor deposited film 8 of α-NPD and TPB, which functions as a hole transportation layer, light-emitting layers 9 and 10, a vapor deposition film 13 of ADN and TPB that functions as an electron transportation layer, an electron injection layer 14 and an upper electrode 15. TPB, which functions as a blue dopant, is added to the vapor deposited film 13 of ADN and TPB, which functions as an electron transportation layer, but as shown in the second embodiment, blue light is prevented from being emitted.

Meanwhile, a blue dopant is added to the hole transportation layer made of a vapor deposited film 8 of α-NPD and TPB, and therefore, blue light is emitted. However, in the B sub-pixels the efficiency is high, and therefore, it is considered that this structure has the same effects.

### Fourth Embodiment

Next, the organic light-emitting display device according to the fourth embodiment of the present invention is described.

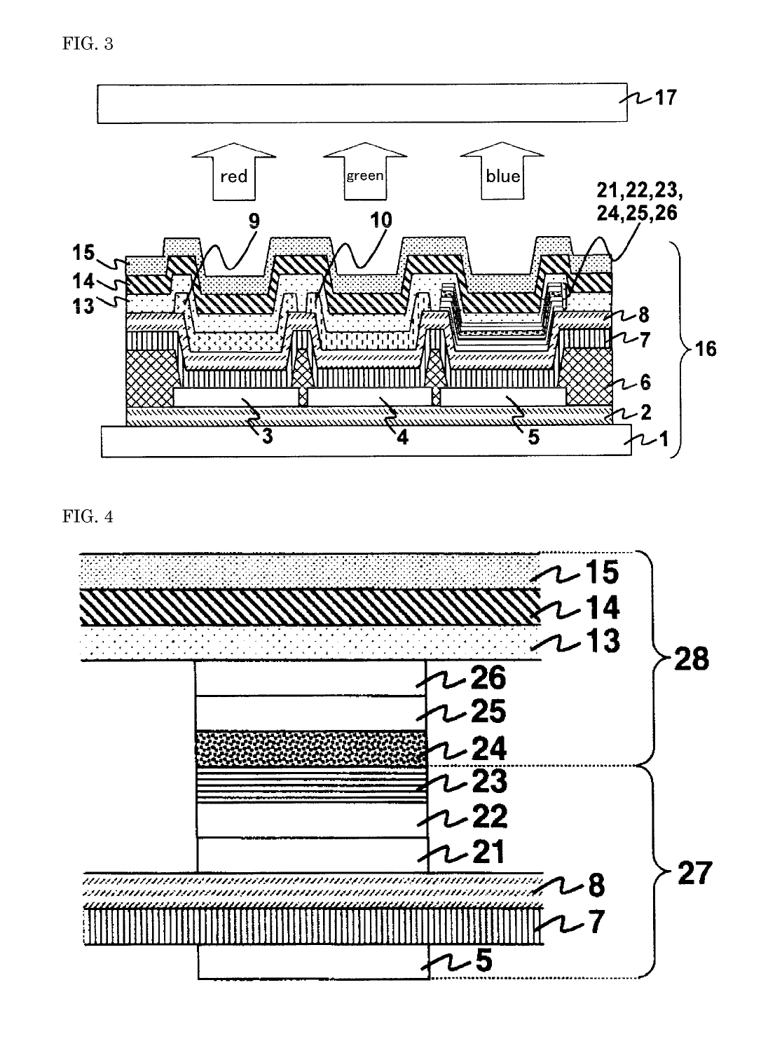

FIG. 3 is a cross sectional diagram showing a pixel of the organic light-emitting display device, and FIG. 4 is a schematic cross sectional diagram showing a B sub-pixel. The present embodiment provides two blue light-emitting layers having the same size as the sub-pixels, and thus, the life of blue light-emitting elements can be prolonged, and the efficiency can be increased.

Concretely, the methods for forming a first interlayer insulating film 2, lower electrodes 3 to 5, a second interlayer insulating film 6, a hole injection layer 7 and a hole transportation layer 8 on a glass substrate 1 are the same as in the first embodiment. In addition, the methods for forming a red light-emitting layer 9 in R sub-pixels and a green light-emitting layer 10 in G sub-pixels are the same as in the first embodiment.

Next, a method for forming a light-emitting layer and a charge generating layer in B sub-pixels is described in reference to FIG. 4.

ADN and TBP are vapor deposited together to form a film as the first light-emitting layer 21. A high-precision mask having a pattern of openings with the same size as the sub-pixels is used for patterning. Next, Alq3 is vapor deposited to form a film as the first electron transportation layer 22. A high-precision mask having a pattern of openings with the same size as the sub-pixels is used to pattern the vapor deposited film. On top of this, an n doped electron transportation layer 23 and a p doped hole transportation layer 24 are formed. The method for forming the transportation layers is the same as in the first embodiment.

Next, an α-NPD vapor deposited film is formed on top of this as a second hole transportation layer 25. The vapor deposited film is also patterned using a high-precision mask having a pattern of openings with the same size as the sub-pixels. Next, on top of this, ADN and TBP are vapor deposited to form a film as a second light-emitting layer 26. The vapor deposited film is also patterned using a high-precision mask having a pattern of openings with the same size as the sub-pixels.

Next, an electron transportation layer 13, an electron injection layer 14 and a cathode 15 are formed. The conditions for fabricating these are the same as in the first embodiment. The thus formed OLED substrate 16 and the facing substrate 17 are used for sealing. The conditions for sealing are the same as in the first embodiment.

R sub-pixels and G sub-pixels have conventional organic light-emitting elements, as in the first embodiment. Meanwhile, as shown in FIG. 4, B sub-pixels exhibit the same properties as when a first blue OLED 27 and a second blue OLED 28 are connected in series.

The first blue OLED 27 is formed of an anode 5, a hole injection layer 7, a hole transportation layer 8, a first light-emitting layer 21, a first electron transportation layer 22 and an n doped electron transportation layer.

In addition, the second blue OLED 28 is formed of a p doped hole transportation layer, a second hole transportation layer 25, a second light emitting layer 26, an electron transportation layer 13, an electron injection layer 14 and a cathode 15. A blue dopant is dispersed in both the first light-emitting layer 21 and the second light-emitting layer 26, and thus, the efficiency is high.

In the present embodiment, a high-precision mask is used for six layers, from the first light-emitting layer 21 to the second light-emitting layer 26. However, the openings in the high-precision mask are in the same locations, and therefore, it is possible to use the same high-precision mask, and the number of high-precision masks used does not increase. In the following embodiments also, a number of layers patterned in the same manner as the sub-pixels are formed, but this can be done using the same mask, for the same reasons as in the present embodiment, and therefore, the number of high-precision masks used is the same.

### Fifth Embodiment

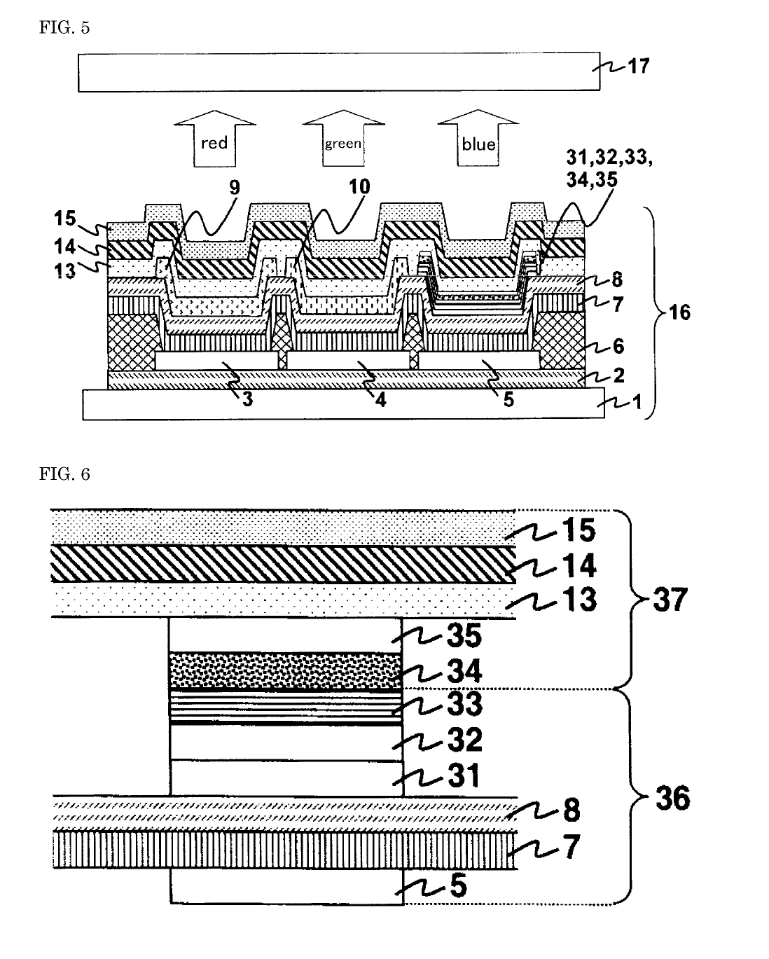

Next, the organic light-emitting display device according to the fifth embodiment of the present invention is described in reference to FIGS. 5 and 6.

FIG. 5 is a cross-sectional diagram showing a pixel of the organic light-emitting display device, and FIG. 6 is a schematic cross-sectional diagram showing a B sub-pixel.

In the present embodiment, a blue light-emitting layer and a common transportation layer of the same size as the sub-pixels function as a blue light-emitting layer, and thus, the life of blue light-emitting elements can be prolonged, and the efficiency can be increased.

Concretely, the method for forming a first interlayer insulating film 2, lower electrodes 3 to 5, a second interlayer insulating film 6, a hole injection layer 7 and a hole transportation layer 8 on a glass substrate 1 is the same as in the first embodiment. In addition, the method for forming a red light emitting layer 9 in R sub-pixels and a green light-emitting layer 10 in G sub-pixels is also the same as in the first embodiment.

Next, the method for forming a light-emitting layer and a charge generating layer in B sub-pixels is described in reference to FIG. 6. A first light-emitting layer 31, a first electron transportation layer 32, an n doped electron transportation layer 33, a p doped hole transportation layer 34 and a second hole transportation layer 35 are formed. The conditions for the manufacture are the same as in the fourth embodiment.

Next, a vapor deposited film 13 of ADN and TPB is formed. The conditions for fabrication are the same as in the second embodiment. On top of this, an electron transportation layer 13, an electron injection layer 14 and a cathode 15 are formed. The conditions for fabricating these are the same as in the first embodiment. The thus formed OLED substrate 16 and facing substrate 17 are used for sealing. The conditions for sealing are the same as in the first embodiment.

R sub-pixels and G sub-pixels are conventional organic light-emitting elements, as in the first embodiment. Meanwhile, as shown in FIG. 6, B sub-pixels have the same properties as when a blue OLED 36 and a second blue OLED 37 are connected in series.

The first blue OLED 36 is formed of an anode 5, a hole injection layer 7, a hole transportation layer 8, a first light-emitting layer 31, a first electron transportation layer 32 and an n doped electron transportation layer 33.

In addition, the second blue OLED 37 is formed of a p doped hole transportation layer 34, a second hole transportation layer 35, a vapor deposited film 13 of ADN and TPB which functions as a light-emitting layer, an electron injection layer 14 and a cathode 15. A blue dopant is added to both the first light-emitting layer 31 and the vapor deposited film 13 of ADN and TPB which functions as a blue light-emitting layer, and thus, the efficiency is high.

### Sixth Embodiment

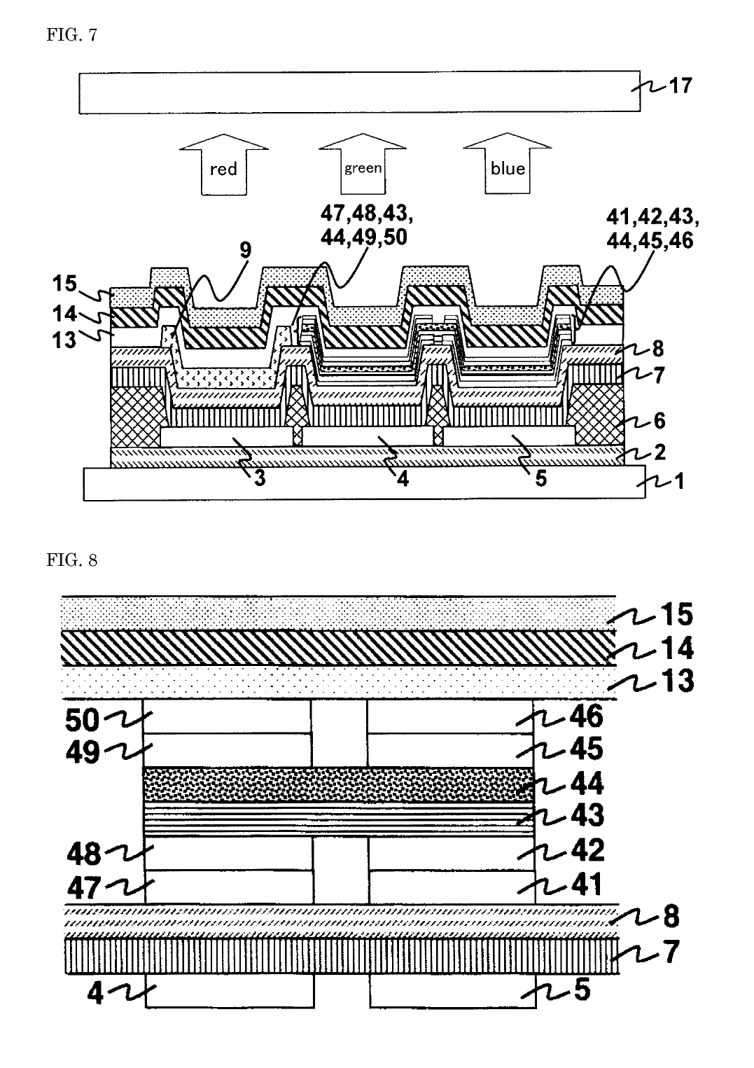

Next, the organic light-emitting display device according to the sixth embodiment of the present invention is described in reference to FIGS. 7 and 8.

FIG. 7 is a cross sectional diagram showing a pixel in the organic light-emitting display device, and FIG. 8 is a schematic cross sectional diagram showing a G sub-pixel and a B sub-pixel.

According to the present embodiment, two light-emitting layers are introduced in G sub-pixels and B sub-pixels, and thus, the life of green light-emitting elements and blue light-emitting elements can be prolonged, and the efficiency can be increased.

Concretely, the method for forming a first interlayer insulating film 2, lower electrodes 3 to 5, a second interlayer insulating film 6, a hole injection layer 7, a hole transportation layer 8 and a red light-emitting layer 9 in R sub-pixels on a glass substrate 1 is the same as in the first embodiment.

Next, the method for forming a light-emitting layer and a charge generating layer in G sub-pixels and B sub-pixels is described in reference to FIG. 8.

In G sub-pixels, CBP and Ir(ppy)₃ are deposited together on the hole transportation layer 8 so as to form a film as a light-emitting layer 47. The vapor deposited film is patterned using a high-precision mask having a pattern of openings with the same size as the sub-pixels. Next, Alq3 is vapor deposited on top of this so as to form a film as an electron transportation layer 48. The vapor deposited film is also patterned to the same size as the sub-pixels.

Next, in B sub-pixels, ADN and TBP are vapor deposited together on top of the hole transportation layer 8 so as to form a film as a light-emitting layer 41, and Alq3 is vapor deposited so as to form a film as an electron transportation layer 42. The conditions for fabrication are the same as in the fourth embodiment.

Next, an n doped electron transportation layer 43 and a p doped hole transportation layer 44 are formed so as to cover the G sub-pixels and the B sub-pixels. The conditions for fabrication are the same as in the first embodiment.

Next, in the G sub-pixels, α-NPD is vapor deposited so as to form a film as a hole transportation layer 49. On top of this, CBP and Ir(ppy)₃ are vapor deposited together so as to form a film as a light-emitting layer 50. The vapor deposited film is patterned using a high-precision mask having a pattern of openings with the same size as the sub-pixels.

Next, in the B sub-pixels, α-NPD is vapor deposited so as to form a film as a hole transportation layer 45. The vapor deposited film is patterned using a high-precision mask having a pattern of openings with the same size as the sub-pixels. On top of this, ADN and TBP are vapor deposited so as to form a film as a light-emitting layer 46. The conditions for fabrication are the same as in the fourth embodiment.

Next, an ADN vapor deposited film 13 is formed over the entire surface of the light-emitting display area as an electron transportation layer. The conditions for fabrication are the same as in the first embodiment. On top of this, an electron injection layer 14 and a cathode 15 are formed. The conditions for fabricating these are the same as in the first embodiment. The thus formed OLED substrate 16 and the facing substrate 17 are used for sealing. The conditions for sealing are the same as in the first embodiment.

In the present embodiment, R sub-pixels are conventional organic light-emitting elements, as in the first embodiment.

Meanwhile, as shown in FIG. 8, G sub-pixels and B sub-pixels have the same properties as when OLED's are connected in series in two stages.

In addition, Ir(ppy)₃, which is a green dopant, is dispersed in the light-emitting layers 47 and 50 of green OLED's.

In addition, TBP, which is a blue dopant, is dispersed in the light-emitting layers 41 and 46 of blue OLED's. Therefore, the efficiency in green light emission and blue light emission is high.

### Seventh Embodiment

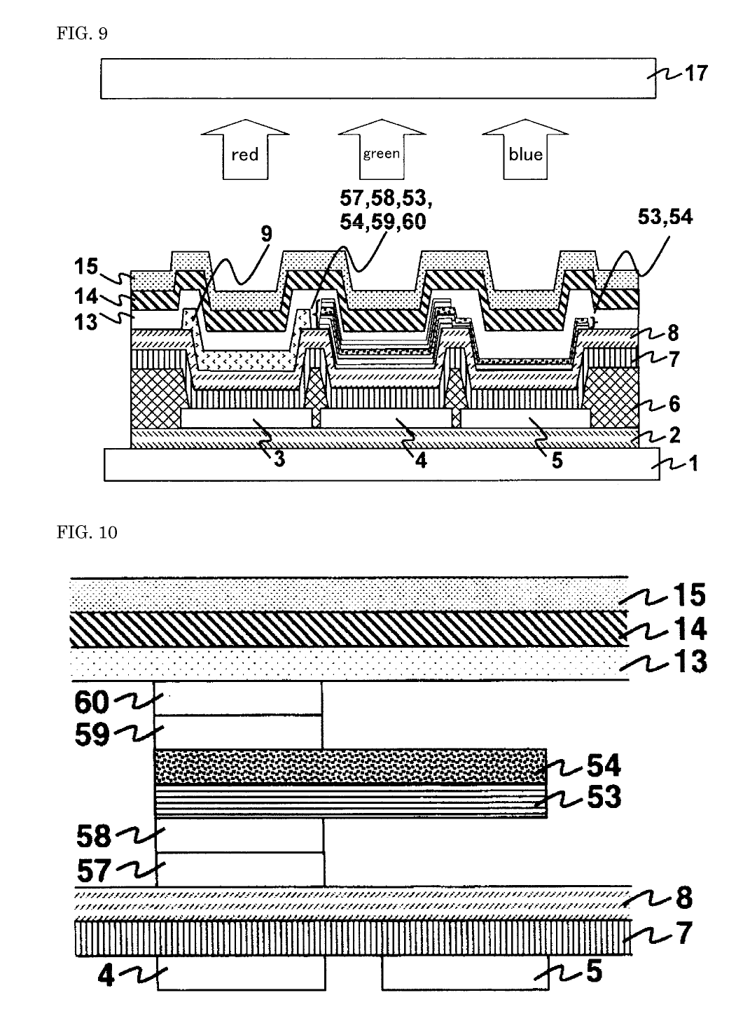

Next, the organic light-emitting display device according to the seventh embodiment of the present invention is described in reference to FIGS. 9 and 10.

FIG. 9 is a cross sectional diagram showing a pixel in the organic light-emitting display device, and FIG. 10 is a schematic cross sectional diagram showing a G sub-pixel and a B sub-pixel.

In the present embodiment, two light-emitting layers are introduced in the G sub-pixels, and thus, the life of green light-emitting elements and blue light-emitting elements can be prolonged, and the efficiency can be increased.

Concretely, the method for forming a first interlayer insulating film, lower electrodes 3 to 5, a second interlayer insulating film 6, a hole injection layer 7, a hole transportation layer 8 and a red light-emitting layer 9 in R sub-pixels on a glass substrate 1 is the same as in the first embodiment.

Next, a method for forming a light-emitting layer and a charge generating layer in G sub-pixels and B sub-pixels is described in reference to FIG. 10. In G sub-pixels, a light-emitting layer 57 and an electron transportation layer 58 are formed on top of the hole transportation layer 8. The conditions for fabrication are the same as in the sixth embodiment.

Next, an n doped electron transportation layer 53 and a p doped hole transportation layer 54 are formed so as to cover the G sub-pixels and the B sub-pixels. The conditions for fabrication are the same as in the sixth embodiment.

Next, in G sub-pixels, a hole transportation layer 59 and a light-emitting layer 60 are formed. The conditions for fabrication are the same as in the sixth embodiment.

Next, a vapor deposition film 13 of ADN and TPB, an electron injection layer 14 and a cathode 15 are formed. The conditions for fabricating these are the same as in the second embodiment. The thus formed OLED substrate 16 and the facing substrate 17 are used for sealing. The conditions for sealing are the same as in the first embodiment.

In the present embodiment, R sub-pixels are conventional organic light-emitting element, as in the first embodiment.

Meanwhile, as shown in FIG. 10, G sub-pixels have the same properties as when OLED's are connected in series in two stages.

In addition, Ir(ppy)₃, which is a green dopant, is added to the light-emitting layers 47 and 50 of green OLED's.

In addition, in the B sub-pixels, the α-NPD vapor deposited film 8 and the vapor deposited film 13 of ADN and TPB function as light-emitting layers, as in the first embodiment. TBP, which is a blue dopant, is added to the vapor deposited film 13 of ADN and TPB. Therefore, the efficiency in green light emission and blue light emission is high.

### Eight Embodiment

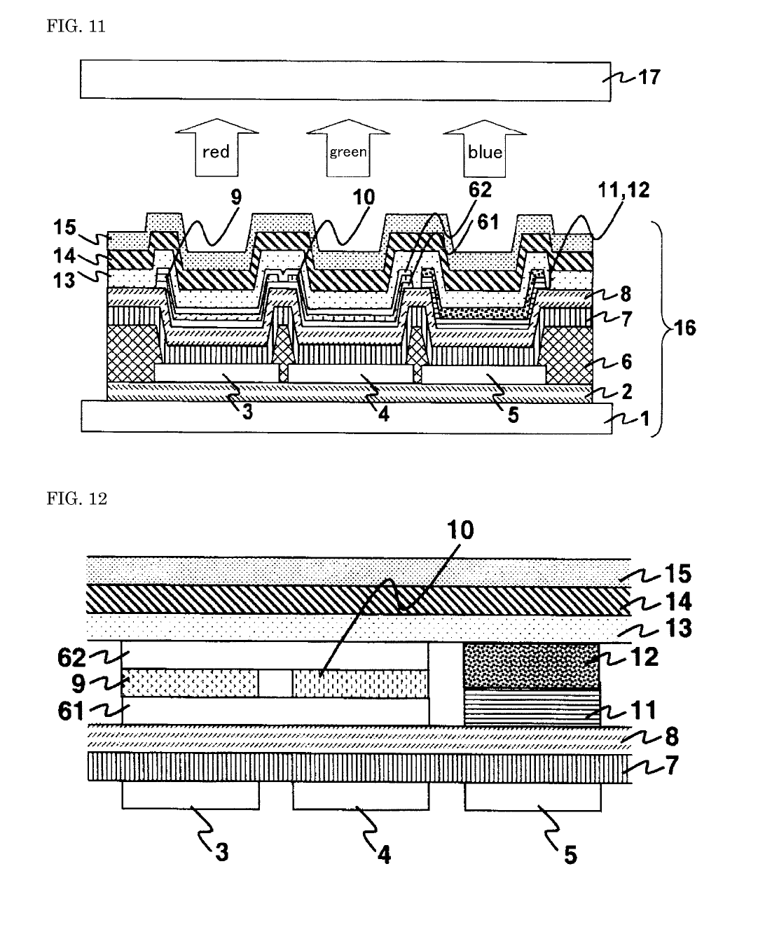

Next, the organic light-emitting display device according to the eighth embodiment of the present invention is described in reference to FIGS. 11 and 12.

FIG. 11 is a cross sectional diagram showing a pixel in the organic light-emitting display device, and FIG. 12 is a schematic cross sectional diagram showing an R sub-pixel, a G sub-pixel and a B sub-pixel.

In the present embodiment, a carrier block layer is provided on either side of the red light-emitting layer and the green light-emitting layer, and thus, the life of red light-emitting elements and green light-emitting elements can be prolonged, and the efficiency can be increased.

Concretely, the method for forming a first interlayer insulating film 2, lower electrodes 3 to 5, a second interlayer insulating film 6, a hole injection layer 7 and a vapor deposited film 8 of α-NPD and TBP on a glass substrate 1 is the same as in the third embodiment.

Next, the method for forming a light-emitting layer and a charge generating layer in R sub-pixels, G sub-pixels and B sub-pixels is described in reference to FIG. 12. α-NPD is vapor deposited so as to cover the R sub-pixels and the G sub-pixels, and form a film as a hole transportation layer 61.

Next, a light-emitting layer 9 is formed in R sub-pixels. The conditions for fabrication are the same as in the first embodiment.

Next, a light-emitting layer 10 is formed in G sub-pixels. The conditions for fabrication are the same as in the first embodiment. Next, BAlq is vapor deposited so as to cover the R sub-pixels and the G sub-pixels, and form a film which functions as an electron transportation layer 62.

Next, an n doped electron transportation layer 11 and a p doped hole transportation layer 12 are formed so as to cover the B sub-pixels. The conditions for fabrication are the same as in the first embodiment.

Next, a vapor deposited film 13 of ADN and TPB, an electron injection layer 14 and a cathode 15 are formed. The conditions for fabricating these are the same as in the second embodiment. The thus formed OLED substrate 16 and a facing substrate 7 are used for sealing. The conditions for sealing are the same as in the first embodiment.

In the present embodiment, the vapor deposited film 8 of α-NPD and TPB functions as a hole transportation layer in R sub-pixels and G sub-pixels. Though TPB, which is a blue dopant, is added to the vapor deposited film, there is a hole transportation layer 61 which blocks electrons so that they do not propagate from the light-emitting layers 9 and 10, and therefore, the vapor deposited film of α-NPD and TPB does not emit blue light.

In addition, the vapor deposited film 13 of ADN and TPB functions as an electron transportation layer. Though TPB, which is a blue dopant, is added to the vapor deposited film, there is an electron transportation layer which blocks holes so that they do not propagate from the light-emitting layers 9 and 10, and therefore, the vapor deposited film 13 of ADN and TPB does not emit blue light.

Meanwhile, the vapor-deposited film 8 of α-NPD and TPB, as well as the vapor deposited film 13 of ADN and TPB, function as blue light-emitting layers in B sub-pixels. TPB, which is a blue dopant, is added to the two light-emitting layers, and thus, the efficiency in blue light emission is high.

1. An organic light-emitting display device, comprising a multiple types of organic light-emitting elements whose types are divided by emission colors, characterized in that
at least a transportation layer for transporting holes and a transportation layer for transporting electrons are formed throughout the entirety of a display region,
a patterned charge generating layer is formed in the first type of organic light-emitting elements, and
a light-emitting layer is formed in the other types of organic light-emitting elements.

2. The organic light-emitting display device according to claim 1, characterized in that
a dopant for controlling the emission spectrum is added to at least one transportation layer of the above described transportation layers in the organic light-emitting elements having said charge generating layer.

3. The organic light-emitting display device according to claim 1, characterized in that
at least a patterned light-emitting layer is formed between said charge generating layer and said transportation layer.

4. The organic light-emitting display device according to claim 3, characterized in that
a patterned transportation layer is formed between said patterned light-emitting layer and said charge generating layer.

5. The organic light-emitting display device according to claim 1, characterized in that
the organic light-emitting elements having said charge generating layer emit blue light.

6. An organic light-emitting display device, comprising a multiple types of organic light-emitting elements whose types are divided by emission colors, characterized in that
at least a transportation layer for transporting holes and a transportation layer for transporting electrons are formed throughout the entirety of a display region,
a patterned charge generating layer is formed in both first and second types of organic light-emitting elements, and
a light-emitting layer is formed in other types of organic light-emitting elements.

7. The organic light-emitting display device according to claim 6, characterized in that
a dopant for controlling the emission spectrum is added to at least one transportation layer from among said transportation layers.

8. The organic light-emitting display device according to claim 6, characterized in that
a patterned light-emitting layer is formed in at least one type of organic light-emitting elements from among the two types of organic light-emitting elements having said charge generating layer.

9. The organic light-emitting display device according to claim 8, characterized in that
a patterned transportation layer is formed between said patterned light-emitting layer and said charge generating layer.

10. The organic light-emitting display device according to claim 6, characterized in that
the two types of organic light-emitting elements having said charge generating layer emit blue and green light.

11. The organic light-emitting display device according to claim 1, characterized in that
said charge generating layer is formed of a multilayer film of an n doped electron transportation layer and a p doped hole transportation layer.

12. An organic light-emitting display device, comprising a number of first organic light-emitting elements which emit light of at least one color and a number of second organic light-emitting elements which emit light of a color that is different from that of said first organic light-emitting elements, characterized in that
each organic light-emitting element has a pair of electrodes for applying a voltage to each element, and a hole transportation layer for transporting holes and an electron transportation layer for transporting electrons which are provided between said electrodes and run throughout the entirety of the display region,
said first organic light-emitting elements have a light-emitting layer between said hole transportation layer and said electron transportation layer separately from said second elements,
said second organic light-emitting elements have a charge generating layer which is provided between said hole transportation layer and said electron transportation layer separately from said first elements, and
at least either said hole transportation layer or said electron transportation layer is a layer for emitting light in said second organic light-emitting elements.

13. The organic light-emitting display device according to claim 12, characterized in that
said first organic light-emitting elements are organic light-emitting elements for emitting green light and organic light-emitting elements for emitting red light, and
said second organic light-emitting elements are organic light-emitting elements for emitting blue light.

14. The organic light-emitting display device according to claim 12, characterized in that
at least either said hole transportation layer or said electron transportation layer includes a dopant for providing light with the same color as that of light emitted by said second organic light-emitting elements.

15. The organic light-emitting display device according to claim 12, characterized in that
a hole injection layer is provided between said hole transportation layer and one electrode, and
an electron injection layer is provided between said electron transportation layer and the other electrode.

16. The organic light-emitting display device according to claim 12, characterized in that
said charge generating layer is a multilayer film of an n doped electron transportation layer provided so as to make contact with the hole transportation layer and a p doped hole transportation layer provided so as to make contact with the electron transportation layer.
